(19) United States
(12) Patent Application Publication
(10) Pub. No.: US 2025/0218780 A1
(43) Pub. Date: Jul. 3, 2025

(54) FABRICATION METHOD OF SEMICONDUCTOR DEVICE

(71) Applicant: FUJI ELECTRIC CO., LTD., Kanagawa (JP)

(72) Inventor: Kaname MITSUZUKA, Matsumoto-city (JP)

(21) Appl. No.: 18/929,412

(22) Filed: Oct. 28, 2024

(30) Foreign Application Priority Data
Dec. 27, 2023 (JP) 2023-222034

(51) Int. Cl. H01L 21/266

(52) U.S. Cl. CPC H01L 21/266

(57) ABSTRACT

A method includes: forming a mask above the semiconductor substrate such that a covering density for a predetermined first region of the semiconductor substrate by the mask is higher than a covering density for a predetermined second region of the semiconductor substrate by the mask; performing ion implantation of a dopant in each of the first region and the second region for forming a second conductivity type region on a front surface of the semiconductor substrate; diffusing the implanted dopant into the semiconductor substrate, where the mask includes a covering portion and an uncovering portion, a width of the covering portion is equal to or greater than 0.25 times and equal to or smaller than 0.8 times a diffusion depth of the dopant, a width of the uncovering portion is equal to or greater than one-third and equal to or smaller than once the width of the covering portion.

The contents of the following patent application(s) are incorporated herein by reference:
NO. 2023-222034 filed in JP on Dec. 27, 2023

### BACKGROUND

### 1. TECHNICAL FIELD

The present invention relates to a fabrication method of a semiconductor device.

### 2. RELATED ART

Patent Document 1 discloses a semiconductor device including a semiconductor substrate in which an IGBT region and a diode region are defined, where an impurity concentration of an anode layer of the diode region is lowered to reduce carriers accumulated in the diode during free wheeling and reduce a recovery loss.

### PRIOR ART DOCUMENT

### Patent Document

Patent Document 1: Japanese Patent Application Publication No. 2021-52078

### BRIEF DESCRIPTION OF THE DRAWINGS

FIG. 1 is a diagram showing an example of a front surface of a semiconductor device 100 according to the example 1.

FIG. 2 is an enlarged view of a region A in FIG. 1.

FIG. 3A is a diagram showing an example of a cross section a-a′ in FIG. 2.

FIG. 3B is a diagram showing an example of a cross section b-b′ in FIG. 2.

FIG. 4 is a flow diagram showing an example of a fabrication method of the semiconductor device 100 according to the example 1.

FIG. 5A is a diagram showing an example of a fabrication method of the semiconductor device 100 according to the example 1.

FIG. 5B is a diagram showing an example of a fabrication method of the semiconductor device 100 according to the example 1.

FIG. 6A is a diagram showing an example of a fabrication method of the semiconductor device 100 according to the example 1.

FIG. 6B is a diagram showing an example of a fabrication method of the semiconductor device 100 according to the example 1.

FIG. 7A is a diagram showing an example of a fabrication method of the semiconductor device 100 according to the example 1.

FIG. 7B is a diagram showing an example of a fabrication method of the semiconductor device 100 according to the example 1.

FIG. 7C is a diagram showing an example of a fabrication method of the semiconductor device 100 according to the example 1.

FIG. 7D is a diagram showing an example of a fabrication method of the semiconductor device 100 according to the example 1.

FIG. 8 is a diagram showing an example of a front surface of a semiconductor device 200 according to the example 2.

FIG. 9 is a diagram showing an example of a fabrication method of the semiconductor device 200 according to the example 2.

FIG. 10A is a diagram showing another example of a fabrication method of the semiconductor device 200 according to the example 2.

FIG. 10B is a diagram showing another example of a fabrication method of the semiconductor device 200 according to the example 2.

FIG. 11A is a diagram showing an example of a front surface of a semiconductor device 300 according to the example 3.

FIG. 11B is a diagram showing an example of a cross section f-f′ in FIG. 11A.

FIG. 12 is a diagram showing an example of a fabrication method of the semiconductor device 300 according to the example 3.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

In the present specification, one side in a direction parallel to a depth direction of a semiconductor substrate is referred to as “front”, and the other side is referred to as “back”. One surface of two principal surfaces of a substrate, a layer, or other member is referred to as a front surface, and the other surface is referred to as a back surface. The “front” and “back” directions are not limited to a direction of gravity, or a direction in which the semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the +Z axis direction and the −Z axis direction are directions opposite to each other. When the Z axis direction is described without describing the signs, it means that the direction is parallel to the +Z axis and the −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. In the present specification, the direction of the Z axis may be referred to as the depth direction. In addition, in the present specification, a direction parallel to the front surface and the back surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a description of a P+ type or an N+ type means a higher doping concentration than that of a P type or an N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. In the present specification, an example will be described where the first conductivity type is the P type and the second conductivity type is the N type. However, the first conductivity type may be the N type and the second conductivity type may be the P type.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

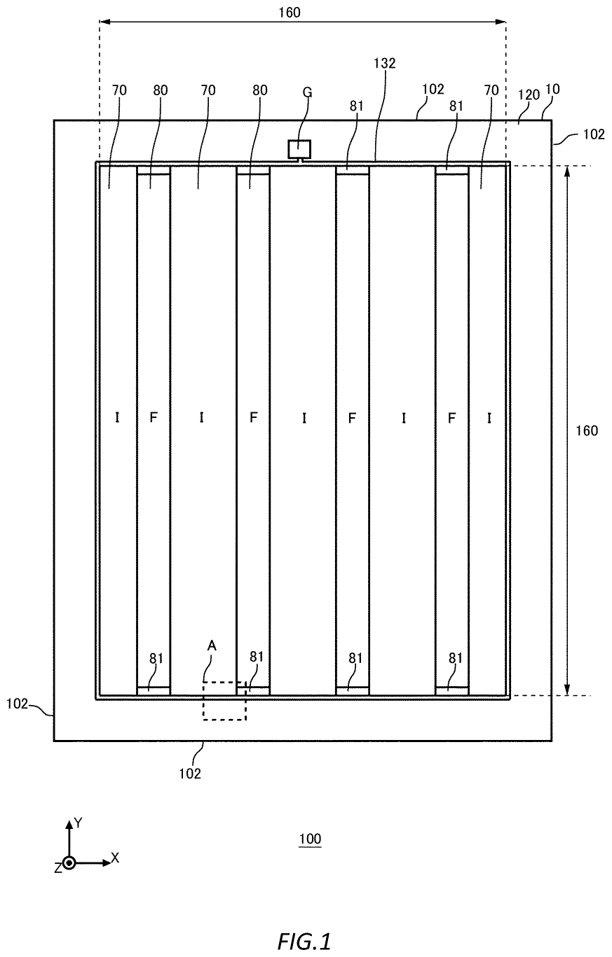

FIG. 1 is a diagram showing an example of a front surface of a semiconductor device 100 according to the example 1. FIG. 1 illustrates a position of each member as being projected onto a front surface of a semiconductor substrate 10. FIG. 1 shows merely some members of the semiconductor device 100, and omits illustrations of some members.

The semiconductor device 100 includes the semiconductor substrate 10. The semiconductor substrate 10 has an end side 102 in the top view. As simply used herein, unless otherwise specified, a top view means a view from the side of the front surface of the semiconductor substrate 10. The semiconductor substrate 10 of the present example includes two sets of end sides 102 facing each other in the top view. In FIG. 1, the X axis and the Y axis are parallel to any of end sides 102. In addition, the Z axis is perpendicular to the front surface of the semiconductor substrate 10.

In the semiconductor substrate 10, an active region 160 is provided. The active region 160 refers to a region where main currents flow in the depth direction between the front surface and the back surface of the semiconductor substrate 10, when the semiconductor device 100 is operated. Above the active region 160, an emitter electrode is provided, but it is omitted in FIG. 1.

In the active region 160, there is provided at least one of a transistor portion 70 which includes a transistor device such as an IGBT, and a diode portion 80 which includes a diode device such as a free wheeling diode (FWD). In the example of FIG. 1, the transistor portion 70 and the diode portion 80 are alternately arranged along a predetermined array direction (the X axis direction, in the present example) on the front surface of the semiconductor substrate 10. In another example, the active region 160 may be provided with only one of the transistor portions 70 and the diode portions 80.

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in a top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

The diode portion 80 includes a cathode region of an N+ type in a region in contact with the back surface of the semiconductor substrate 10. In the present specification, a region where the cathode region is provided is referred to as the diode portion 80. In other words, the diode portion 80 is a region that overlaps with the cathode region in the top view. The back surface of the semiconductor substrate 10 may be provided with a collector region of a P+ type in a region other than the cathode region. In the present specification, an extension region 81 extending from the diode portion 80 to a gate runner described later in the Y axis direction may also be included in the diode portion 80. The back surface of the extension region 81 is provided with the collector region.

The transistor portion 70 includes a collector region of a P+ type in a region in contact with the back surface of the semiconductor substrate 10. Further, in the transistor portion 70, an emitter region of an N type, a base region of a P type, and a gate structure having a gate conductive portion and a gate dielectric film are periodically arranged on the front surface side of the semiconductor substrate 10.

The semiconductor device 100 may have one or more pads above the semiconductor substrate 10. As an example, the semiconductor device 100 shown in FIG. 1 has a gate pad G, which is, however, only an example. The semiconductor device 100 may have a pad such as an anode pad, a cathode pad, and a current detection pad. Each pad is arranged in the vicinity of the end side 102. The vicinity of the end side 102 refers to a region between the end side 102 and the emitter electrode in a top view. When the semiconductor device 100 is mounted, each pad may be connected to an external circuit through a wiring such as a wire.

A gate potential is applied to the gate pad G. The gate pad G is electrically connected to a conductive portion of a gate trench portion of the active region 160. The semiconductor device 100 includes a gate runner which connects the gate pad G and the gate trench portion.

The gate runner 48 is arranged between the active region 160 and the end side 102 of the semiconductor substrate 10 in the top view. The gate runner 48 of the present example is configured to enclose the active region 160 in the top view. A region surrounded by the gate runner in the top view may also be defined as the active region 160. The gate runner 48 may be formed of polysilicon doped with impurities or the like.

The semiconductor device 100 of the present example is provided with an edge termination structure portion 120 between the active region 160 and the end side 102. The edge termination structure portion 120 of the present example is arranged between the gate runner 48 and the end side 102. The edge termination structure portion 120 reduces the electric field strength in the front surface side of the semiconductor substrate 10. The edge termination structure portion 120 may include a plurality of guard rings. The guard ring is a region of the P type in contact with the front surface of the semiconductor substrate 10. A plurality of guard rings are provided such that a depletion layer in the front surface side of the active region 160 can be extended to the outside and the breakdown voltage of the semiconductor device 100 can be improved. The edge termination structure portion 120 may further include at least one of a field plate and an RESURF, which is annularly provided to surround the active region 160.

In addition, the semiconductor device 100 may also be provided with a temperature sense portion (not illustrated) which is a PN junction diode formed of polysilicon or the like, and a current detection portion (not illustrated) which operates similarly to the transistor portion provided in the active region 160.

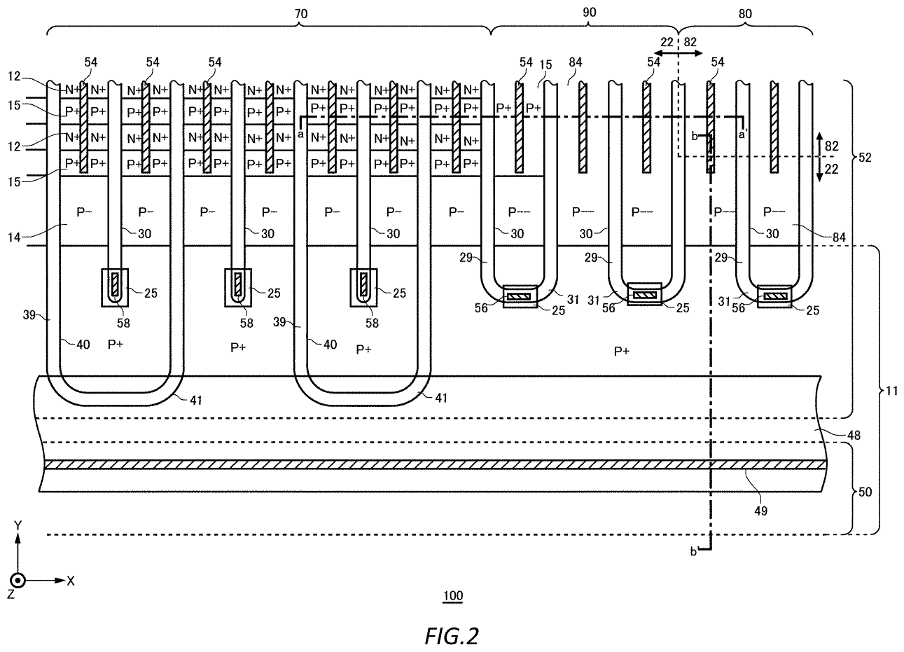

FIG. 2 is an enlarged view of a region A in FIG. 1. The region A includes a transistor portion 70 and a diode portion 80.

The semiconductor device 100 of the present example includes a gate trench portion 40, a dummy trench portion 30, a well region 11, an emitter region 12, a base region 14, an anode region 84 and a contact region 15 that are provided inside the front surface side of the semiconductor substrate 10. The gate trench portion 40 and the dummy trench portion 30 each are an example of the trench portion. In addition, the semiconductor device 100 of the present example includes an emitter electrode 52 provided above the front surface of the semiconductor substrate 10. The emitter electrode 52 and the gate runner 48 are provided to be isolated from each other.

An interlayer dielectric film is provided between the emitter electrode 52 and the gate runner 48 and the front surface of the semiconductor substrate 10, which is omitted in FIG. 2. In the interlayer dielectric film of the present example, contact holes 49, 54, and 56 are provided to extend through the interlayer dielectric film. In FIG. 2, each contact hole is hatched with inclined lines.

The emitter electrode 52 is provided above the gate trench portion 40, the dummy trench portion 30, the well region 11, the emitter region 12, the base region 14, the anode region 84 and the contact region 15. The emitter electrode 52 is in contact with the emitter region 12, the contact region 15, the anode region 84 and the base region 14 on the front surface of the semiconductor substrate 10, through the contact hole 54. In addition, the emitter electrode 52 is connected to a dummy conductive portion in the dummy trench portion 30 through the contact hole 56. The emitter electrode 52 may be connected to the dummy conductive portion of the dummy trench portion 30 at an edge of the dummy trench portion 30 in the Y axis direction.

The gate runner 48 is connected to a gate conductive portion in the gate trench portion 40 on the front surface of the semiconductor substrate. The gate runner 48 is not connected to the dummy conductive portion in the dummy trench portion 30. The gate runner 48 of the present example is provided from a position below the contact hole 49 to an edge portion of the gate trench portion 40. A dielectric film such as an oxide film is provided between the gate runner 48 and the front surface of the semiconductor substrate 10. At the edge portion of the gate trench portion 40, the gate conductive portion is exposed to the front surface of the semiconductor substrate. The gate trench portion 40 is in contact with the gate runner 48 through the exposed portion of the gate conductive portion. The gate runner 48 may be formed simultaneously when the gate conductive portion is deposited.

The emitter electrode 52 is formed of a metal containing material. For example, at least a part of a region of each electrode is formed of aluminum or aluminum-silicon alloy. Each electrode may have a barrier metal formed of titanium, a titanium compound, or the like as an underlying layer of a region formed of aluminum or the like. In addition, each electrode may have a plug formed of tungsten or the like in the contact hole. Below the contact hole with a plug, a plug region 17 of the P++ type having a doping concentration higher than that of the contact region 15 may be provided. The plug region 17 improves latch-up capability by improving a contact resistance between the barrier metal and the contact region 15.

The well region 11 is provided overlapping the gate runner 48. The well region 11 is also provided so as to extend with a predetermined width in a range not overlapping the gate runner 48. The well region 11 of the present example is provided away from the end of the contact hole 54 in the Y axis direction towards the gate runner 48. The well region 11 is a region of a second conductivity type having a higher doping concentration than that of the base region 14. The base region 14 of this example is a P− type, and the well region 11 is a P+ type. In addition, the well region 11 is formed from the front surface of the semiconductor substrate 10 to a position deeper than a lower end of the base region 14.

Each of the transistor portion 70 and the diode portion 80 has a plurality of trench portions arrayed in an array direction. In the transistor portion 70 in this example, one or more gate trench portions 40 and one or more dummy trench portions 30 are alternately provided along the array direction. In the diode portion 80 in this example, the plurality of dummy trench portions 30 are provided along the array direction. In the diode portion 80 in this example, the gate trench portion 40 is not provided.

The gate trench portion 40 in the present example may include two linear portions 39 extending along an extending direction perpendicular to the array direction (trench portions which are linear along the extending direction), and the edge portion 41 connecting the two linear portions 39. The extending direction in FIG. 2 is the Y axis direction.

Preferably, at least a part of the edge portion 41 is provided in a curved shape in the top view. The edge portion 41 connects the end portions in the Y axis direction of two linear portions 39, so that the electric field strength in the end portion of the linear portion 39 can be reduced.

In the transistor portion 70, the dummy trench portion 30 is provided between the respective linear portions 39 of the gate trench portion 40. Between the respective linear portions 39, one dummy trench portion 30 may be provided, or a plurality of dummy trench portions 30 may be provided. The dummy trench portion 30 may have a straight shape extending in the extending direction, or may have linear portions 29 and an edge portion 31 similarly to the gate trench portion 40. The semiconductor device 100 shown in FIG. 2 includes both of the straight shaped dummy trench portion 30 having no edge portion 31, and the dummy trench portion 30 having the edge portion 31.

A diffusion depth of the well region 11 may be deeper than the depth of the gate trench portion 40 and the dummy trench portion 30. End portions of the gate trench portion 40 and the dummy trench portion 30 in the Y axis direction are provided in the well region 11 in the top view. In other words, the bottom portion in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the front surface of the semiconductor substrate 10. The depth position of the lower end of the mesa portion is the same as the depth position of the lower end of the trench portion. The mesa portion of the present example is sandwiched between trench portions that are adjacent to each other in the X axis direction, and is provided to extend in the extending direction (the Y axis direction) along the trench on the front surface of the semiconductor substrate 10. In the present example, mesa portions 60 are provided in the transistor portion 70, and mesa portions 61 are provided in the diode portion 80. In a case of simply mentioning “mesa portion” in the present specification, the portion refers to each of a mesa portion 60 and a mesa portion 61.

The mesa portion 60 is provided adjacent to at least one of the dummy trench portion 30 or the gate trench portion 40 in the transistor portion 70.

The mesa portion 60 includes the well region 11, the emitter region 12 and the contact region 15 on the front surface of the semiconductor substrate 10. The mesa portion 61 is provided in direct contact with the dummy trench portion 30 in the diode portion 80. The mesa portion 61 includes the well region 11 and the anode region 84 on the front surface of the semiconductor substrate 10.

The base region 14 is a region in the transistor portion 70, which is provided on the front surface side of the semiconductor substrate 10. The base region 14 of the present example is, for example, of the P− type.

On the front surface of each mesa portion 60, at least one of the emitter region 12 of the first conductivity type and the contact region 15 of the second conductivity type may be provided. The emitter region 12 of the present example is of the N+ type, and the contact region 15 is of the P+ type. The emitter region 12 and the contact region 15 may be provided between the base region 14 and the front surface of the semiconductor substrate 10 in the depth direction.

The mesa portion 60 has the emitter region 12 exposed to the front surface of the semiconductor substrate 10. The emitter region 12 is provided in contact with the gate trench portion 40. The mesa portion 60 in contact with the gate trench portion 40 may be provided with the contact region 15 exposed to the front surface of the semiconductor substrate 10.

Each of the contact region 15 and the emitter region 12 in the mesa portion 60 is provided to extend from one trench portion to the other trench portion in the X axis direction. As an example, the contact regions 15 and the emitter regions 12 in the mesa portion 60 are alternately arranged along the extending direction of the trench portion (the Y axis direction).

In another example, the contact regions 15 and the emitter regions 12 of the mesa portion 60 may be provided in a striped pattern along the extending direction of the trench portion (the Y axis direction). For example, the emitter region 12 is provided in a region in contact with the trench portion, and the contact region 15 is provided in a region interposed between the emitter regions 12.

The front surface of the mesa portion 61 is provided with the anode region 84. In the present example, the emitter region 12 is not provided on the front surface of the mesa portion 61. The front surface of the mesa portion 61 may be provided with the contact region 15. The anode region 84 of the present example is of a P−− type, as an example. A doping concentration of the anode region 84 in the present example is lower than a doping concentration of the base region 14. In the present example, by lowering the doping concentration of the anode region 84, holes can be prevented from being injected during reverse recovery. Note that the doping concentration of the anode region 84 may be the same as the doping concentration of the base region 14 in another example. In this case, the base region 14 and the anode region 84 can be formed in the same process.

The contact hole 54 is provided above each mesa portion. The contact hole 54 is provided above each region of the emitter region 12 and the contact region 15 in the mesa portion 60 of the transistor portion 70. The contact hole 54 is also provided above the anode region 84 in the mesa portion 61 of the diode portion 80. The contact hole 54 may be arranged at the center of each mesa portion in the array direction (the X axis direction). No contact holes 54 are provided above the well regions 11 provided at both ends in the Y axis direction. In this way, the interlayer dielectric film is provided with one or more contact holes 54. The contact hole 54 of the present example may be provided to extend in the Y axis direction.

In the diode portion 80, a cathode region 82 of the N+ type is provided in a region in direct contact with the back surface of the semiconductor substrate 10. On the back surface of the semiconductor substrate 10, a region in which the cathode region 82 is not provided may be provided with a collector region 22 of the P+ type. In FIG. 2, a boundary between the cathode region 82 and the collector region 22 is indicated by a dotted line. A boundary between the collector region 22 and the cathode region 82 is a boundary between the transistor portion 70 and the diode portion 80.

The cathode region 82 is arranged away from the well region 11 in the Y axis direction. With this configuration, the distance between a region of the P type (the well region 11) having a comparatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

The semiconductor device 100 may include a boundary region 90 provided between the transistor portion 70 and the diode portion 80. The boundary region 90 is a region in which the collector region 22 is provided on the back surface of the semiconductor substrate 10 and therefore may be a part of the transistor portion 70. However, including a front surface structure different from those of the other regions in the transistor portion 70, the boundary region 90 will be described to be distinguished from the transistor portion 70 in the present specification.

The front surface of the mesa portion 60 of the boundary region 90 is provided with the anode region 84. However, the front surface of the mesa portion 60 closest to the transistor portion 70 may be provided with the contact region 15 extending in the Y axis direction. The boundary region 90 includes the dummy trench portion 30 and does not include the gate trench portion 40. The boundary region 90 is provided such that an effect of a hole injected from the contact region 15 of the transistor portion 70 during reverse recovery of the diode portion 80 can be reduced.

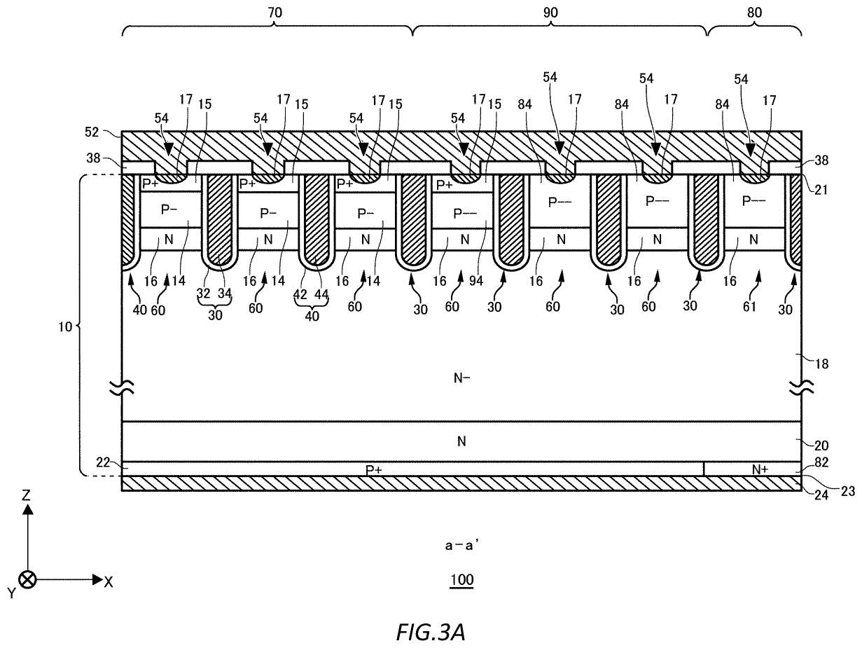

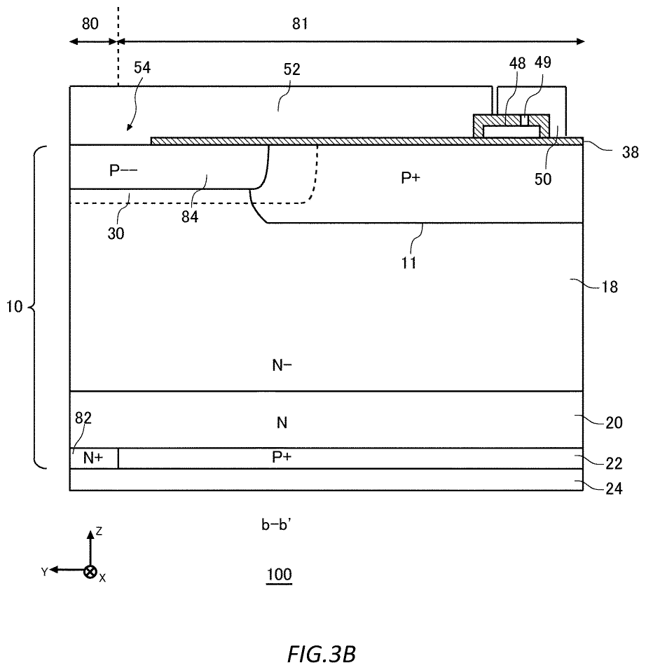

FIG. 3A is a diagram showing an example of a cross section a-a′ in FIG. 2. FIG. 3B is a diagram showing an example of a cross section b-b′ in FIG. 2. The a-a′ cross section is an XZ plane which passes through the contact region 15, the base region 14, the anode region 84, the gate trench portion 40 and the dummy trench portion 30. In the cross section a-a′, the semiconductor device 100 in the present example has the semiconductor substrate 10, the interlayer dielectric film 38, the emitter electrode 52, and a collector electrode 24.

The interlayer dielectric film 38 is provided on the front surface 21 of the semiconductor substrate 10. The interlayer dielectric film 38 is a dielectric film such as silicate glass added with impurities of, for example, boron, phosphorus, or the like. The interlayer dielectric film 38 may be in contact with the front surface 21, and another film such as an oxide film may be provided between the interlayer dielectric film 38 and the front surface 21. The interlayer dielectric film 38 is provided with a contact hole 54 described with reference to FIG. 2.

The emitter electrode 52 is provided on the front surface 21 of the semiconductor substrate 10 and the front surface of the interlayer dielectric film 38. The emitter electrode 52 is electrically connected to the front surface 21 of the semiconductor substrate 10 through the contact hole 54 of the interlayer dielectric film 38. In the contact hole 54, a contact plug such as tungsten (W) may be provided. The collector electrode 24 is provided on a back surface 23 of the semiconductor substrate 10. The emitter electrode 52 and the collector electrode 24 are formed of a metal containing material.

The semiconductor substrate 10 may be a silicon substrate, may be a silicon carbide substrate, or may be a nitride semiconductor substrate such as gallium nitride, or the like. In the present example, the semiconductor substrate 10 is a silicon substrate.

The semiconductor substrate 10 includes a drift region 18 of a first conductivity type. The drift region 18 of the present example is of the N− type. The drift region 18 may be a remaining region in the semiconductor substrate 10 in which the other doping regions have not been provided.

Above the drift region 18, one or more accumulation regions 16 may be provided in the Z axis direction. The accumulation region 16 is a region where the same dopant as that of the drift region 18 is accumulated at a higher concentration than the drift region 18. The doping concentration of the accumulation region 16 is higher than the doping concentration of the drift region 18. With the provision of the accumulation region 16, it is possible to increase an injection enhancement effect (IE effect) of the carrier so as to lower the ON voltage.

Above the base region 14 in the transistor portion 70, the emitter region 12 is provided to be in contact with the front surface 21 of the semiconductor substrate 10. The emitter region 12 is provided in contact with the gate trench portion 40. The doping concentration of the emitter region 12 is higher than the doping concentration of the drift region 18. Examples of the dopant of the emitter region 12 include arsenic (As), phosphorus (P), antimony (Sb), and the like.

The buffer region 20 of a first conductivity type may be provided below the drift region 18. The buffer region 20 of the present example is of the N type. The doping concentration of the buffer region 20 is higher than the doping concentration of the drift region 18. The buffer region 20 may function as a field stop layer to prevent a depletion layer that spreads from the back surface side of the base region 14 from reaching the collector region 22 and the cathode region 82.

In the diode portion 80, the cathode region 82 is provided below the buffer region 20. The cathode region 82 may be provided at the same depth of that of the collector region 22 of the transistor portion 70. The diode portion 80 may function as a free wheeling diode (FWD) which allows the free wheeling current to flow in the reverse direction when the transistor portion 70 is turned off.

In the transistor portion 70, the collector region 22 is provided below the buffer region 20. The collector region 22 may be provided to be in contact with the cathode region 82 on the back surface 23 of the semiconductor substrate 10.

In the semiconductor substrate 10, the gate trench portion 40 and the dummy trench portion 30 are provided. The gate trench portion 40 and the dummy trench portion 30 are provided to extend from the front surface 21 of the semiconductor substrate 10 through the doping region such as the base region 14 or the anode region 84 to reach the drift region 18. The configuration of the trench portion extending through the doping region is not limited to the one manufactured in the order of forming the doping region and then forming the trench portion. The configuration of the trench portions extending through the doping region also includes a configuration of forming the trench portions and then forming the doping region between the trench portions.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided inside the gate dielectric film 42 in the gate trench. The front surface of the gate conductive portion 44 may be in the same XY plane as the front surface 21. The gate dielectric film 42 insulates the gate conductive portion 44 from the semiconductor substrate 10. The gate conductive portion 44 is formed of a semiconductor such as polysilicon doped with impurities.

The gate conductive portion 44 may be provided longer than the base region 14 in the depth direction of the semiconductor substrate 10. The gate trench portion 40 is covered with the interlayer dielectric film 38 on the front surface 21. When a predetermined voltage is applied to the gate conductive portion 44, a channel is formed by an electron inversion layer in a surface layer of the base region 14 at a boundary in contact with the gate trench.

The dummy trench portion 30 may have the same structure as the gate trench portion 40 in the XZ cross section. The dummy trench portion 30 has a dummy trench, a dummy dielectric film 32, and a dummy conductive portion 34 that are provided at the front surface 21 of the semiconductor substrate 10. The dummy dielectric film 32 is provided to cover an inner wall of the dummy trench. The dummy dielectric film 32 may be formed by oxidizing or nitriding the semiconductor of the inner wall of the dummy trench. The dummy conductive portion 34 is provided inside the dummy dielectric film 32 in the dummy trench. The front surface of the dummy conductive portion 34 may be in the same XY plane as the front surface 21 of the semiconductor substrate 10. The dummy dielectric film 32 insulates the dummy conductive portion 34 from the semiconductor substrate 10. The dummy conductive portion 34 may be formed of the same material as the gate conductive portion 44.

The gate trench portion 40 and the dummy trench portion 30 of the present example are covered with the interlayer dielectric film 38 on the front surface 21 of the semiconductor substrate 10. Note that the bottom portions of the dummy trench portion 30 and the gate trench portion 40 may be formed in a curved-surface shape (a curved shape in the cross section) convexly downward.

When the diode portion 80 is brought into conduction, an electron current flows from the cathode region 82 to the anode region 84. When the electron current reaches the anode region 84, conductivity modulation occurs and hole current flows from the anode region 84. In addition, the electron current diffused from the cathode region 82 facilitates holes to be injected from the contact region 15 of the transistor portion 70, and thereby hole density increases in the semiconductor substrate 10. As a result, increased time required for the hole to disappear when the diode portion 80 is turned off increases the reverse recovery peak current and increases the reverse recovery loss.

A technique for preventing such a hole current is known, in which a lifetime control region including lifetime killers is provided in the front surface side of the semiconductor substrate. The lifetime killer is, as an example, an electron beam implanted in the entire semiconductor substrate, helium, an electron beam or proton implanted to a predetermined depth, or the like. The lifetime control region is a crystal defect formed in the semiconductor substrate due to the implantation of the lifetime killer. The lifetime control region facilitates electrons and holes, which are generated when a diode portion is brought into conduction, to be eliminated in recombination, and thus reduces reverse recovery losses.

In the present example, the lifetime control region including the lifetime killer is not provided in the front surface 21 side of the semiconductor substrate 10. In the present example, the doping concentration of the anode region 84 is lower than the doping concentration of the base region 14 such that the hole injection can be reduced during reverse recovery, even if the lifetime control region is not provided.

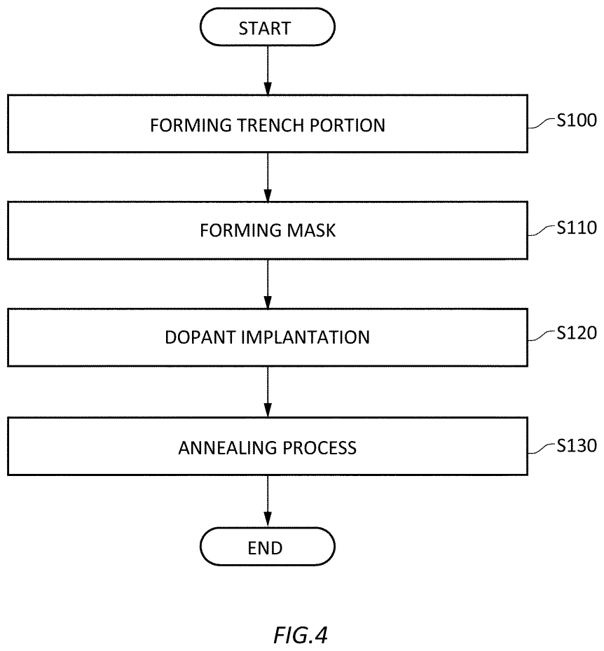

FIG. 4 is a flow diagram showing an example of a fabrication method of the semiconductor device 100 according to the example 1. FIG. 4 mainly shows the dopant implantation process and the annealing process for forming the base region 14 and the anode region 84. The base region 14 and the anode region 84 are an example of the second conductivity type region.

In the present example, a plurality of trench portions are formed in the semiconductor substrate 10 of the N− type (step S 100), and subsequently a mask is formed above the semiconductor substrate 10 (step S 110). Here, the semiconductor substrate 10 includes predetermined first region and second region. The mask is formed to have a covering density for the second region higher than a covering density for the first region.

Then, the ion implantation of the P type dopant is performed through the mask in each of the first region and the second region, and subsequently the mask is removed (step S 120). The dopant of the P type is, as an example, boron.

Subsequently, the annealing process is performed (step S 130). This facilitates the implanted dopant of the P type to be thermally diffused in the semiconductor substrate 10 so that a second conductivity type region having a higher doping concentration is formed in the first region with a lower covering density and a second conductivity type region having a lower doping concentration is formed in the second region with a higher covering density. In this manner, the mask having different covering densities is used for the first region and the second region predetermined in the semiconductor substrate 10 such that the second conductivity type regions having different doping concentrations can be formed in one process.

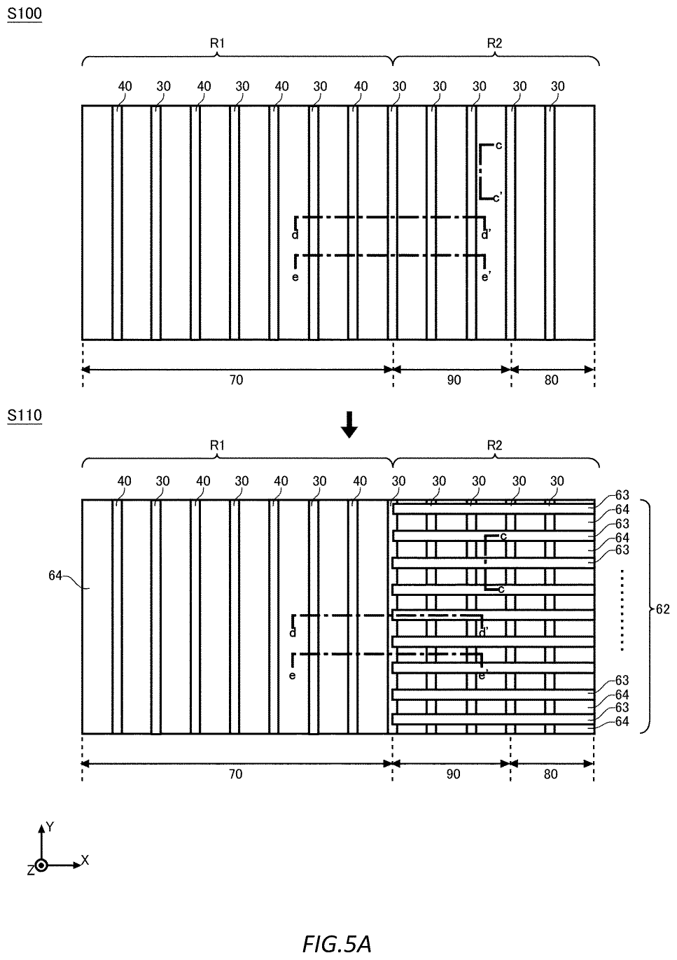

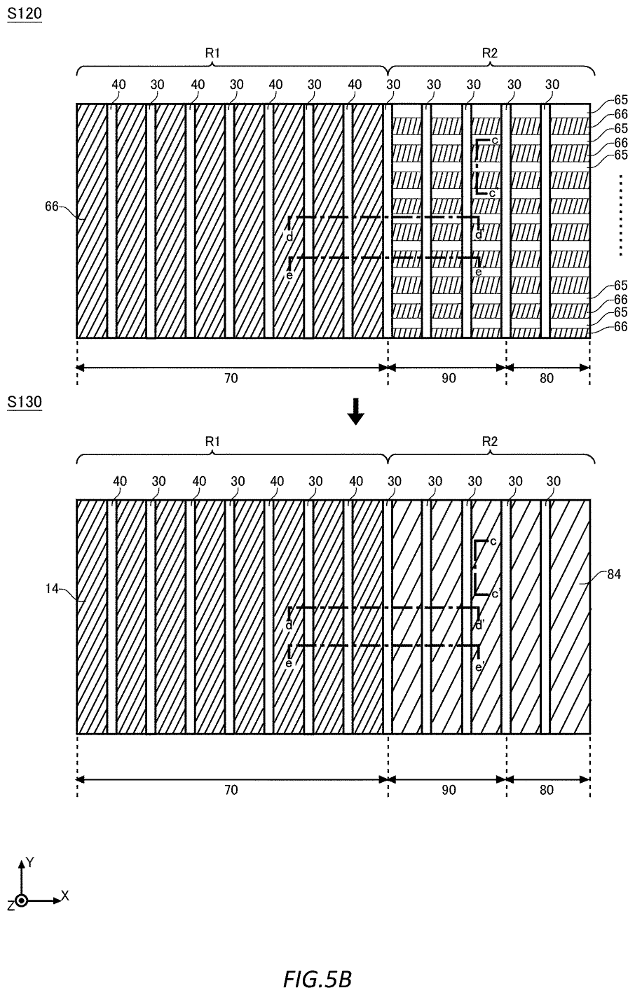

Then, the fabrication method of the semiconductor device 100 described in FIG. 4 will be described again with reference to the top view and the cross sectional view of the semiconductor substrate 10. FIG. 5A and FIG. 5B are diagrams showing an example of the fabrication method of the semiconductor device 100 according to the example 1. FIG. 5A and FIG. 5B show an example of a schematic top view of the semiconductor substrate 10.

In step S 100, the gate trench portion 40 and the dummy trench portion 30 are formed in the semiconductor substrate 10. The semiconductor substrate 10 includes the predetermined first region R1 and second region R2. The first region R1 is a region in which the dopant is implanted such that the first region R1 has a doping concentration higher than that of the second region R2. The first region R1 of the present example is a region where the transistor portion 70 is formed and the second region R2 of the present example is a region where the diode portion 80 is formed. The second region R2 may further include a region where the boundary region 90 is formed.

In step S 110, a mask 62 is formed above the semiconductor substrate 10. The mask 62 of the present example is a resist mask. The mask 62 includes covering portions 63 formed in a striped pattern extending in the X axis direction and uncovering portions 64. A covering density of the covering portions 63 of the present example is proportional to the total area ratio of the covering portions 63. In other words, in a top view of the semiconductor substrate 10, an area ratio of the covering portions 63 in the first region R1 is lower than an area ratio of the covering portions 63 in the second region R2. Therefore, a width of the covering portion 63 and a width of the uncovering portion 64 are adjusted such that a doping concentration of the second conductivity type region to be formed can be adjusted. Above the first region R1 of the present example, only the uncovering portions 64 are formed and the covering portions 63 are not formed. Above the second region R2 of the present example, a plurality of covering portions 63 and a plurality of uncovering portions 64 are formed. That is, the entire front surface 21 of the semiconductor substrate 10 is exposed in the first region R1 of the present example, while the front surface 21 of the semiconductor substrate 10 is exposed in part through the uncovering portions 64 in the second region R2 of the present example.

In step S 120, the ion implantation of the P type dopant is performed through the mask 62 in each of the first region R1 and the second region R2. That is, the P type dopant is implanted in the entire first region and a portion of the second region R2 corresponding to the uncovering portions 64. Subsequently, the mask 62 is removed. In FIG. 5B, an implanted region 65 where the dopant is implanted is hatched with inclined lines to be distinguished from a non-implanted region 66. Subsequently, in step S 130, the annealing process is performed such that the implanted P type dopant is thermally diffused in the semiconductor substrate 10 to form the second conductivity type region.

In the second region R2, the P type dopant implanted through the uncovering portions 64 onto the front surface 21 of the semiconductor substrate 10 is thermally diffused. In this manner, the second conductivity type region having a lower doping concentration (anode region 84) can be formed in the second region R2 than that of the second conductivity type region in the first region R1 (base region 14).

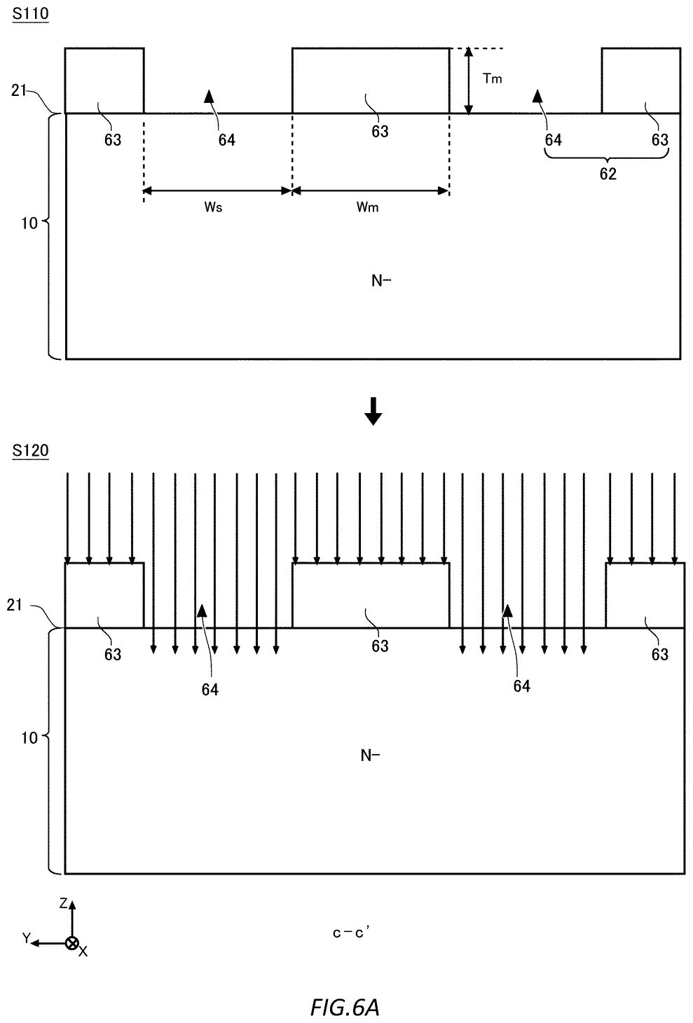

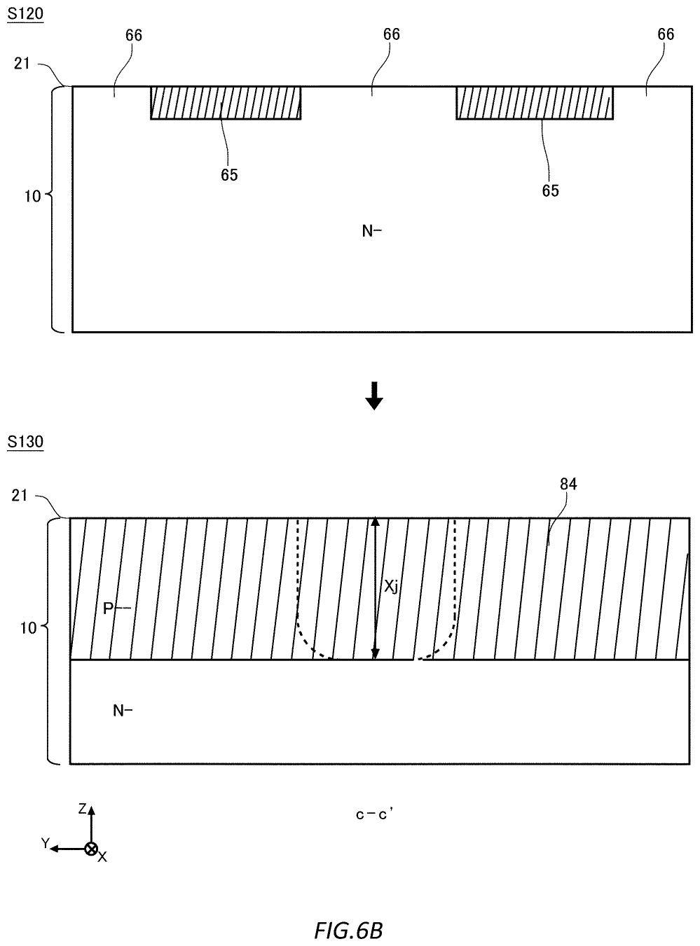

FIG. 6A and FIG. 6B are diagrams showing an example of the fabrication method of the semiconductor device 100 according to the example 1. FIG. 6A and FIG. 6B show a cross section c-c′ in FIG. 5A. The cross section c-c′ is an example of a YZ plane in the second region R2 where the mask 62 is formed.

A plurality of trench portions are formed in the semiconductor substrate 10 (not shown), and subsequently, the mask 62 is formed above the semiconductor substrate 10 (step S 110). In the Y axis direction, the covering portion 63 has a width Wm and the uncovering portion 64 has a width Ws. The width Wm of the covering portion 63 of the present example is equal to or greater than 0.25 times and equal to or smaller than 0.8 times a diffusion depth Xj of the dopant which will be described below and the width Ws of the uncovering portion 64 is equal to or greater than one-third and equal to or smaller than once the width Wm of the covering portion 63. As an example, the width Wm of the covering portion 63 is equal to or greater than 0.5 μm and equal to or smaller than 1.6 μm.

Then, the ion implantation of the P type dopant is performed through the mask 62, and subsequently the mask 62 is removed (step S 120). In FIG. 6B, an implanted region 65 where the dopant is implanted is hatched with inclined lines to be distinguished from a non-implanted region 66. Subsequently, the annealing process is performed (step S 130). This facilitates the implanted P type dopant to be thermally diffused in the semiconductor substrate 10 to form the second conductivity type region. Here, the diffusion depth Xj of the dopant refers to a distance from the front surface 21 of the semiconductor substrate 10 to the lower end of the second conductivity type region in the Z axis direction.

In the second region R2, the dopant is implanted onto only a portion of the front surface 21 of the semiconductor substrate 10 exposed through the uncovering portions 64 and the dopant is not implanted in a portion below the covering portions 63. However, the implanted dopant is thermally diffused through the annealing process to form the second conductivity type region throughout the second region R2.

The covering portion 63 and the uncovering portion 64 of the present example have the width Wm and width Ws within the numerical range described above, respectively, with reference to the diffusion depth Xj of the dopant. This can form the second conductivity type region having a uniform profile. In addition, the width Wm of the covering portion 63 and the width Ws of the uncovering portion 64 are adjusted within the numerical range described above such that the second conductivity type region having a desired doping concentration can be formed.

In addition, a thickness Tm of the covering portion 63 of the present example is equal to or greater than 0.3 μm and equal to or smaller than 3 μm. This prevents the dopant implantation below the covering portions 63 without preventing the dopant implantation through the uncovering portions 64.

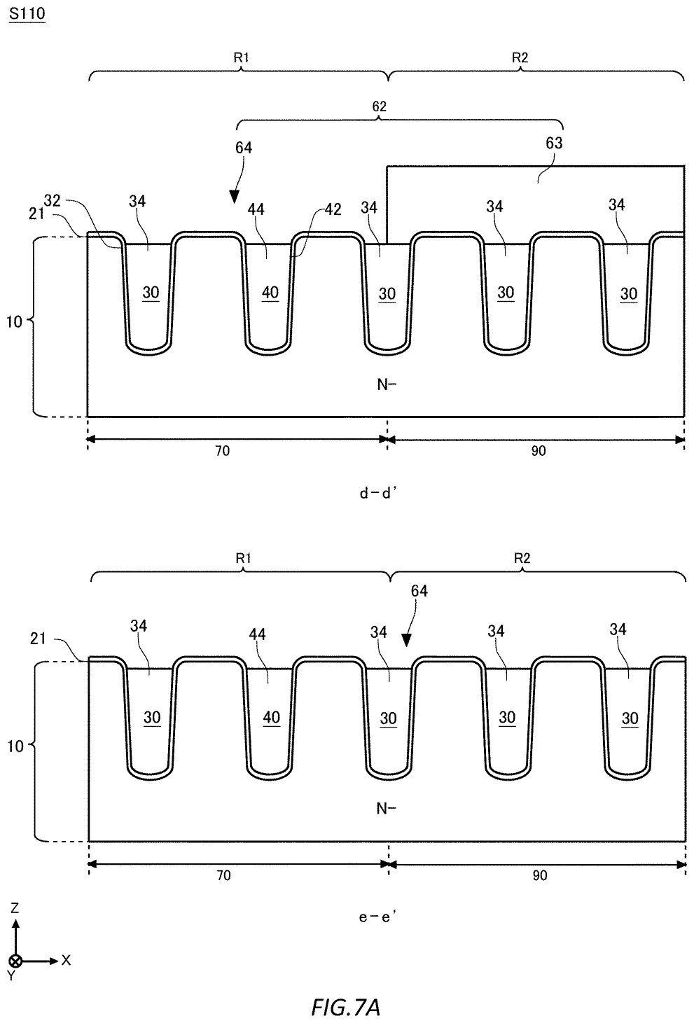

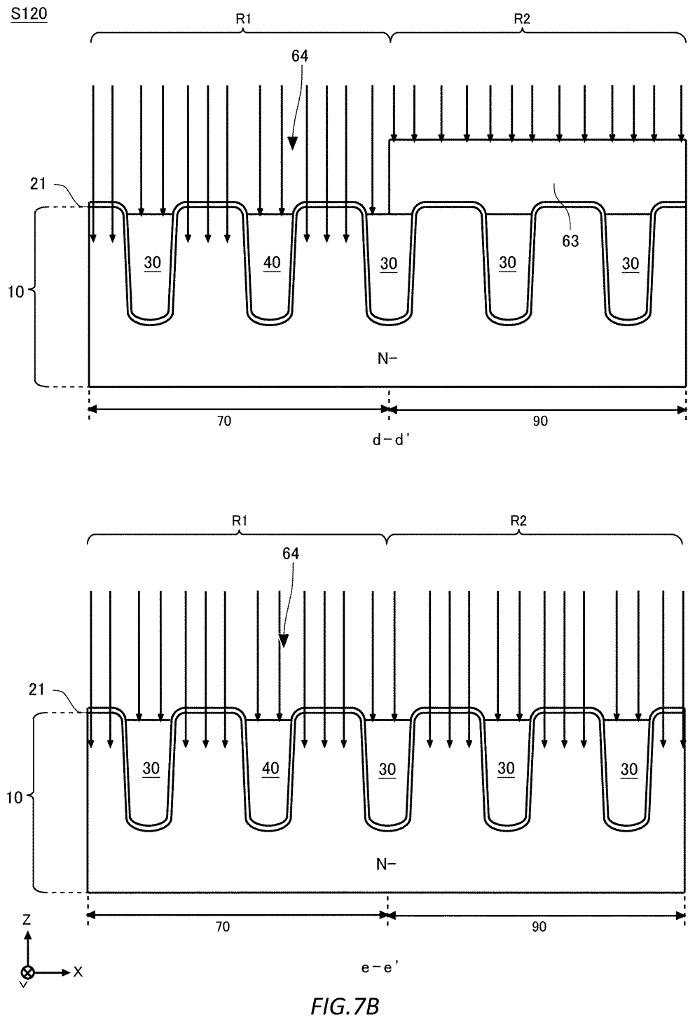

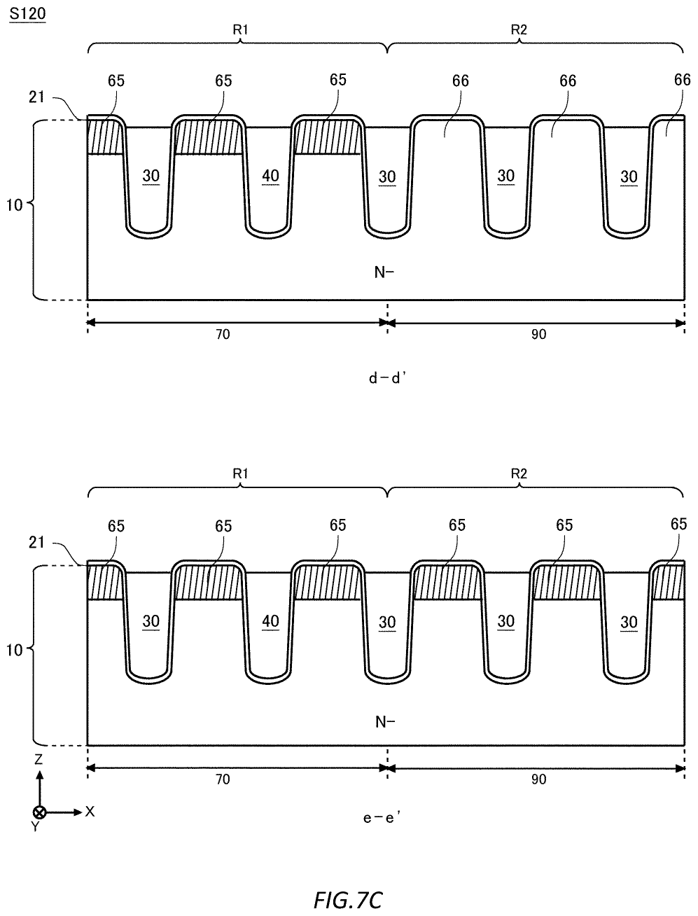

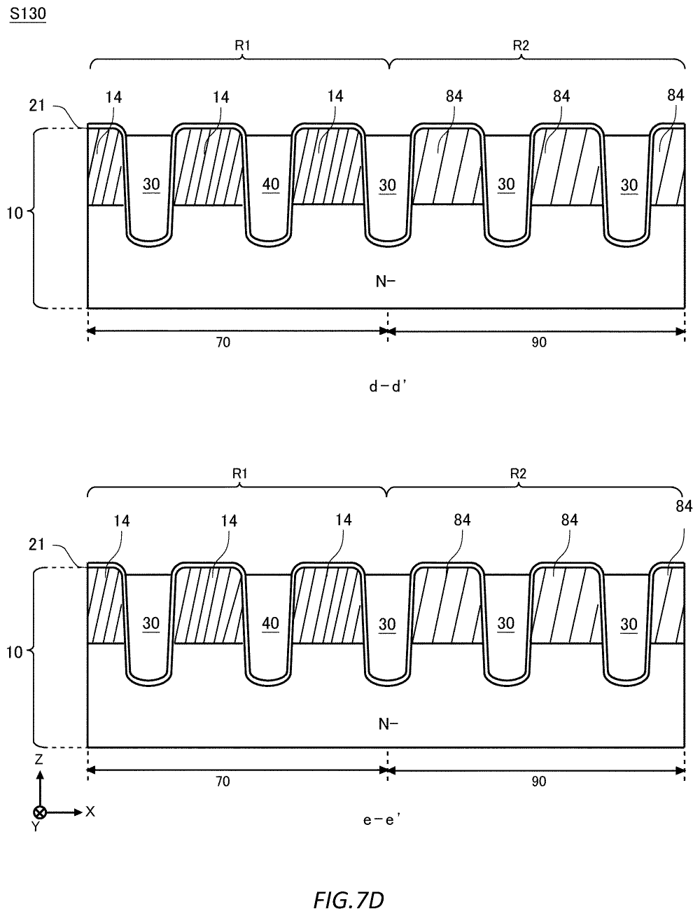

FIG. 7A to FIG. 7D are diagrams showing an example of the fabrication method of the semiconductor device 100 according to the example 1. Each of FIG. 7A to FIG. 7D shows the cross section d-d′ and the cross section e-e′ in FIG. 5A to be compared to each other. The cross section d-d′ and the cross section e-e′ are an example of an XZ plane passing through a plurality of trench portions in the first region R1 and the second region R2.

As shown in FIG. 7A, in step S 100, the gate trench portion 40 and the dummy trench portion 30 are formed in the semiconductor substrate 10, and in step S 110, the mask 62 is formed above the semiconductor substrate 10. In the second region R2, the cross section d-d′ passes through the covering portion 63 and the cross section e-e′ passes through the uncovering portion 64.

Then, as shown in FIG. 7B and FIG. 7C, in step S 120, the ion implantation of the P type dopant is performed in each of the first region R1 and the second region R2, and subsequently, the mask 62 is removed. In FIG. 7C, an implanted region 65 where the dopant is implanted is hatched with inclined lines to be distinguished from a non-implanted region 66. As shown in the cross section d-d′, below the covering portion 63 is the non-implanted region 66 where the P type dopant is not implanted, and as shown in the cross section e-e′, below the uncovering portion 64 is the implanted region 65 where the P type dopant is implanted.

Subsequently, as shown in FIG. 7D, in step S 130, the annealing process is performed such that the implanted P type dopant is thermally diffused in the semiconductor substrate 10 to form the second conductivity type region. In the second region R2, the dopant is also thermally diffused from the implanted region 65 to the non-implanted region 66 to form the second conductivity type region having a uniform profile.

In this manner, according to the fabrication method of the semiconductor device 100 according to the present example, the mask having different covering densities is used for the first region and the second region of the semiconductor substrate 10 such that the second conductivity type regions having different doping concentrations can be formed in one process.

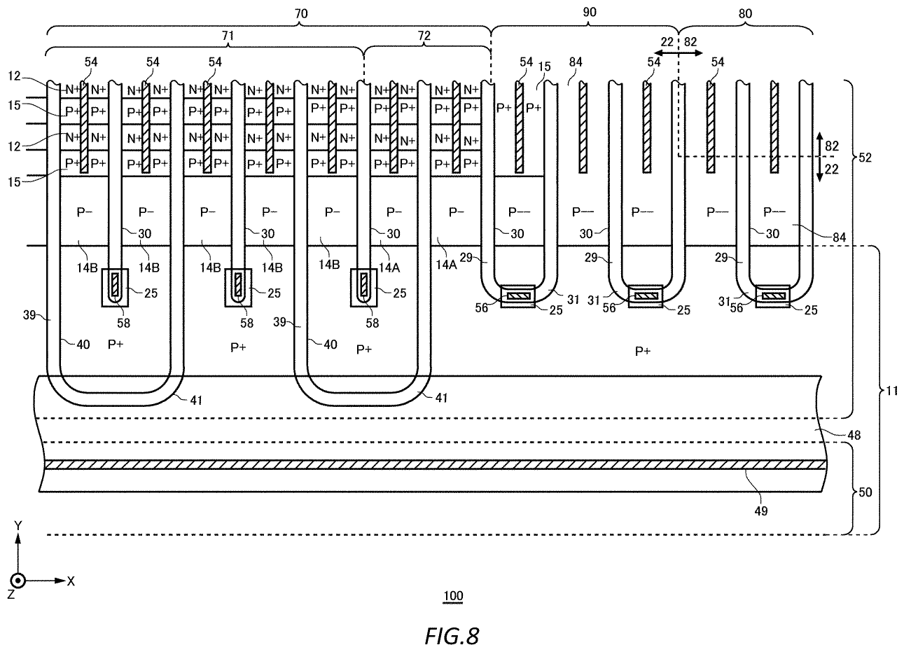

FIG. 8 is a diagram showing an example of a front surface of a semiconductor device 200 according to the example 2. In the present example, the transistor portion 70 includes a main region 71 and an end region 72, which is different from the semiconductor device 100 according to the example 1. Here, components included in the semiconductor device 100 are provided with the same reference signs and will not be described, and a difference from the semiconductor device 100 will mainly be described.

The transistor portion 70 of the present example includes the main region 71 provided to be spaced apart from the diode portion 80 in a top view of the semiconductor substrate 10 and the end region 72 provided at the end of the diode portion 80 side. The end region 72 of the present example is provided to be adjacent to the boundary region 90. A width of the end region 72 of the present example in the X axis direction is equal to or greater than 20 μm and equal to or smaller than 100 μm.

A doping concentration of the base region 14 of the end region 72 (the base region 14A in FIG. 8) is higher than a doping concentration of the base region 14 of the main region 71 (the base region 14B in FIG. 8). The doping concentration of the base region 14A is equal to or greater than 1.5 times and equal to or smaller than twice the doping concentration of the base region 14B. When the transistor portion 70 is turned on, an electron current flows from the emitter region 12 of the transistor portion 70 toward the cathode region 82 of the diode portion 80, the conductivity modulation subsequently occurs, and a defective operation of holes implanted from the collector region 22, called snapback, may occur.

In the semiconductor device 200 of the present example, the doping concentration of the base region 14A of the end region 72 of the transistor portion 70 is higher than the doping concentration of the base region 14B of the main region 71 to suppress the transistor operation of the end region 72 such that the snapback can be reduced.

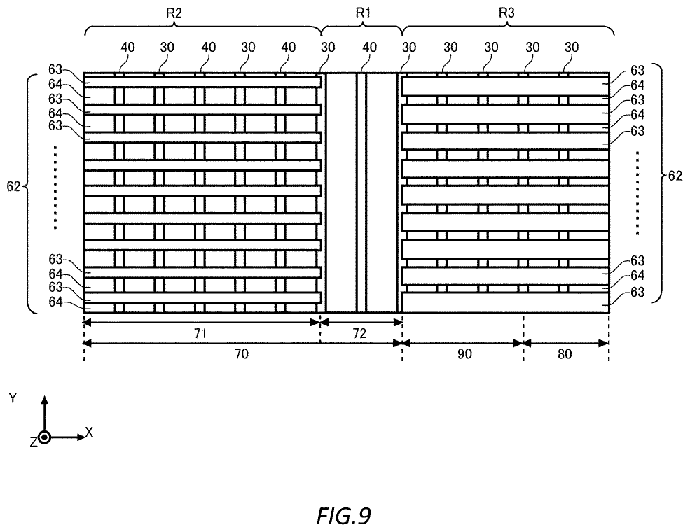

FIG. 9 is a diagram showing an example of a fabrication method of the semiconductor device 200 according to the example 2. FIG. 9 shows step S 110 for forming the mask 62 above the semiconductor substrate 10. The fabrication method of the semiconductor device 200 of the present example includes step S 100 to step S 130, similarly to the fabrication method of the semiconductor device 100 shown in FIG. 4. However, the configuration of the mask 62 is different.

The semiconductor substrate 10 of the present example includes the predetermined first region R1, second region R2, and third region R3. The first region R1 is a region in which the dopant is implanted such that the first region R1 has a doping concentration higher than that of the second region R2 and the second region R2 is a region in which the dopant is implanted such that the second region R2 has a doping concentration higher than that of the third region R3. The first region R1 of the present example is a region where the end region 72 of the transistor portion 70 is formed, the second region R2 of the present example is a region where the main region 71 of the transistor portion 70 is formed, and the third region R3 of the present example is a region where the diode portion 80 is formed. The third region R3 may further include a region where the boundary region 90 is formed.

A width of the covering portion 63 of the first region R1 is smaller than that of the second region R2, which is smaller than that of the third region R3. Therefore, in a top view of the semiconductor substrate 10, an area ratio of the covering portions 63 in the first region R1 is lower than an area ratio of the covering portions 63 in the second region R2 and an area ratio of the covering portions 63 in the second region R2 is lower than an area ratio of the covering portions 63 in the third region R3. Above the first region R1 of the present example, the covering portions 63 are not formed and only the uncovering portions 64 are formed. Above the second region R2 and the third region R3, a plurality of covering portions 63 and a plurality of uncovering portions 64 are formed, and a width of the covering portion 63 is smaller than a width of the covering portion 63 form in the third region R3. An area ratio of the covering portions 63 in the third region R3 may be equal to or greater than 1.5 times and equal to or smaller than three times an area ratio of the covering portions 63 in the second region R2.

In step S 120, the ion implantation of the P type dopant is performed in each of the first region R1, the second region R2, and the third region R3, and subsequently, the dopant is thermally diffused through the annealing process of step S 130. As the covering density of the mask 62 is proportional to a total area ratio of the covering portions 63, in the first region R1, the second conductivity type region having a higher doping concentration (base region 14A) can be formed than that of the second conductivity type region of the second region R2 (base region 14B). In addition, in the third region R3, the second conductivity type region having a lower doping concentration (anode region 84) can be formed than that of the second conductivity type region of the second region R2 (base region 14B).

In this manner, according to the fabrication method of the semiconductor device 200 of the present example, the doping concentration of the base region 14A of the end region 72 of the transistor portion 70 is higher than the doping concentration of the base region 14B of the main region 71 to suppress the transistor operation of the end region 72 such that the snapback can be reduced.

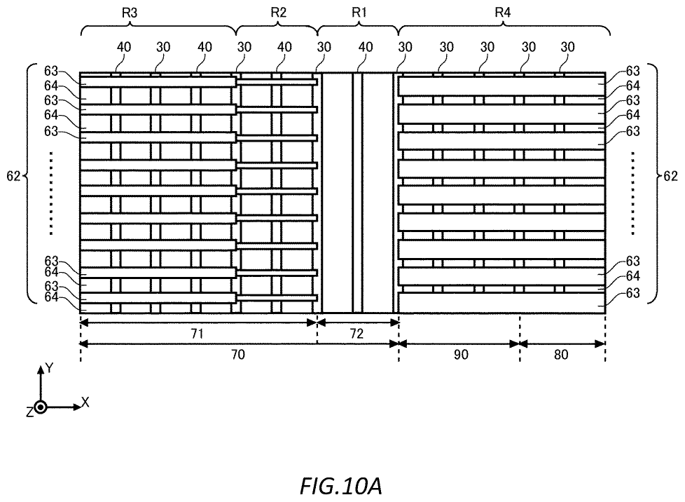

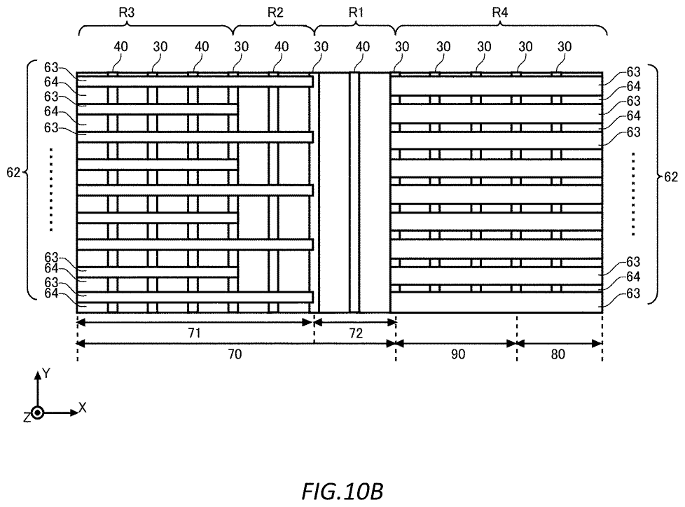

FIG. 10A and FIG. 10B are diagrams showing another example of a fabrication method of the semiconductor device 200 according to the example 2. FIG. 10A and FIG. 10B show the mask 62 having a configuration different from that of FIG. 9.

The semiconductor substrate 10 of the present example includes the predetermined first region R1, second region R2, third region R3, and fourth region R4. The first region R1 is a region in which the dopant is implanted such that the first region R1 has a doping concentration higher than that of the second region R2, the second region R2 is a region in which the dopant is implanted such that the second region R2 has a doping concentration higher than that of the third region R3, and the third region R3 is a region in which the dopant is implanted such that the third region R3 has a doping concentration higher than that of the fourth region R4. The first region R1 of the present example is a region where the end region 72 of the transistor portion 70 is formed. Both of the second region R2 and the third region R3 of the present example correspond to a region included in the main region 71 of the transistor portion 70, and the region corresponding to the third region R3 is spaced apart from the end region 72 side than the region corresponding to the second region R2 is. The fourth region R4 of the present example is a region where the diode portion 80 is formed. The fourth region R4 may further include a region where the boundary region 90 is formed.

As shown in FIG. 10A, a width of each covering portion 63 increases in the order of the first region R1, the second region R2, the third region R3, and the fourth region R4. Therefore, as described above, the doping concentration of the second conductivity type region to be formed decreases in the order of the first region R1, the second region R2, the third region R3, and the fourth region R4.

Alternatively, as shown in FIG. 10B, the width of each covering portion 63 is equal in the first region R1, the second region R2 and the third region R3, and greater in the fourth region R4. A quantity of the covering portions 63 per unit area is the largest in the first region R1 and the fourth region R4, and decreases in the order of the second region R2 and the third region R3. Therefore, similarly to FIG. 10A, the doping concentration of the second conductivity type region to be formed decreases in the order of the first region R1, the second region R2, the third region R3, and the fourth region R4.

In FIG. 10A or FIG. 10B, an area ratio of the covering portions 63 in the third region R3 may be equal to or greater than 1.2 times and equal to or smaller than twice an area ratio of the covering portions 63 in the second region R2. An area ratio of the covering portions 63 in the fourth region R4 may be equal to or greater than 1.5 times and equal to or smaller than three times an area ratio of the covering portions 63 in the third region R3.

In the transistor portion 70 of the present example, the base region 14 having three different doping concentrations is formed. However, this is not limited thereto. The base region 14 having more than three different doping concentrations can be formed. As described above, the covering density of the mask 62 is varied in the respective regions such that the doping concentration of the second conductivity type region formed from the main region 71 of the transistor portion 70 to the end region 72 (base region 14) can be increased gradually and the snapback can effectively be reduced.

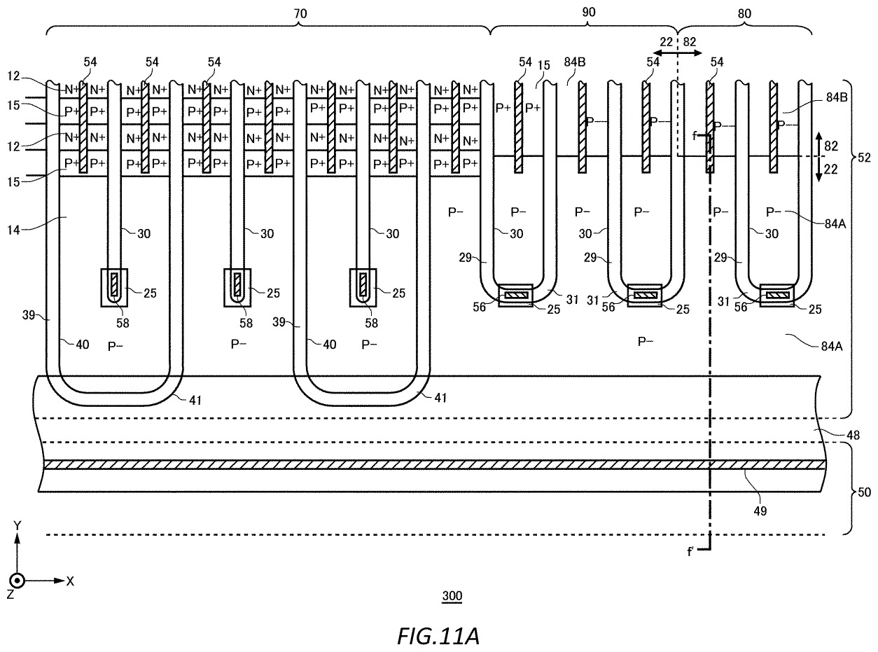

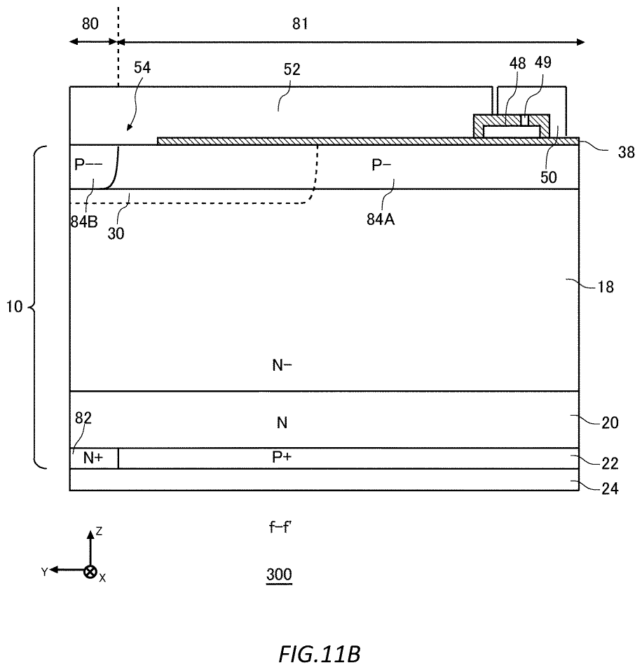

FIG. 11A is a diagram showing an example of a front surface of a semiconductor device 300 according to the example 3. FIG. 11B is a diagram showing an example of a cross section f-f′ in FIG. 11A. The semiconductor device 300 of the present example is different from the semiconductor device 100 according to the example 1 in the range where the base region 14, the anode region 84 and the well region 11 are provided. Here, components included in the semiconductor device 100 are provided with the same reference signs and will not be described, and a difference from the semiconductor device 100 will mainly be described.

The anode region 84 of the present example includes an anode region 84A and an anode region 84B. The anode region 84A is provided at the end side outside the anode region 84B in the Y axis direction to extend to an outer circumference of the active region 160. The doping concentration of the anode region 84A is higher than the doping concentration of the anode region 84B. As an example, the anode region 84A is of the P− type and the anode region 84B is of the P−− type. The doping concentration of the anode region 84A may be the same as the doping concentration of the base region 14. The boundary region 90 of the present example also includes the anode region 84A, similarly to the diode portion 80.

The semiconductor device 300 of the present example does not include the well region 11. Alternatively, in the transistor portion 70, the base region 14 is provided to extend to the outer circumference of the active region 160, and in the boundary region 90, the anode region 84 (anode region 84A) is provided to extend to the outer circumference of the active region 160.

The front surface of the extension region 81 which is the diode portion 80 extended in the Y axis direction is provided with the anode region 84A. The dummy trench portion 30 of the diode portion 80 is provided to extend to the extension region 81. Note that the boundary between the anode region 84A and the anode region 84B may be aligned with or may not be aligned with the boundary between the cathode region 82 and the collector region 22 provided on the back surface 23 of the semiconductor substrate 10 (that is, the boundary between the extension region 81 and the diode portion 80).

During reverse recovery of the diode portion 80, holes accumulated in the edge termination structure portion 120 move intensively to the end of the diode portion 80, which could lead to destructive failure of the end of the contact hole 54. The semiconductor device 300 of the present example is provided with the anode region 84B having a lower doping concentration in the diode portion 80 and provided with the anode region 84A having a doping concentration higher than that of the anode region 84B in the extension region 81 to ensure the desired doping concentration and ensure the withstand capability at the end during reverse recovery. This can omit a process of forming the well region 11 of the P+ type.

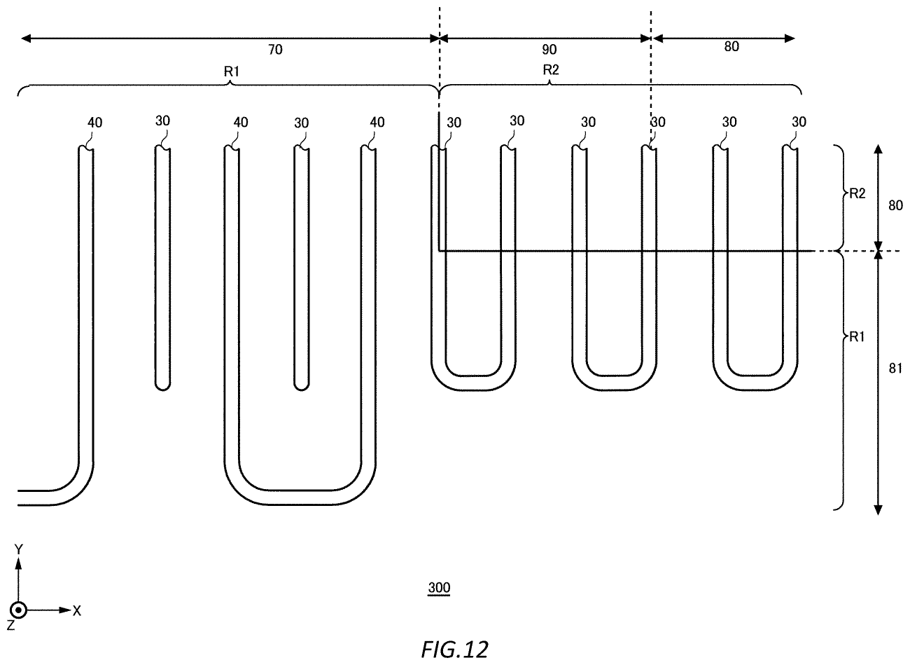

FIG. 12 is a diagram showing an example of a fabrication method of the semiconductor device 300 according to the example 3. The fabrication method of the semiconductor device 300 of the present example includes step S 100 to step S 130, similarly to the fabrication method of the semiconductor device 100 shown in FIG. 4. However, the configurations of the first region R1 and the second region R2 predetermined in the semiconductor substrate 10 are different. FIG. 12 schematically illustrates the configuration of the first region R1 and the second region R2 of the present example.

The first region R1 includes a region where the transistor portion 70 is formed and a region where the extension region 81 is formed. The second region R2 of the present example is a region where the diode portion 80 is formed. The second region R2 may further include a region where the boundary region 90 is formed. The second region R2 is surrounded by the first region R1 in a top view of the semiconductor substrate 10.

The covering densities of the mask for the first region R1 and the second region R2 are different from each other such that the doping concentrations of the second conductivity type region to be formed are different from each other, similarly to the example 1. In the first region R1 of the present example, the base region 14 and the anode region 84A are formed. In the second region R2 of the present example, the anode region 84B is formed. In this manner, the mask having different covering densities is used for the first region and the second region predetermined in the semiconductor substrate 10 such that the second conductivity type regions having different doping concentrations can be formed in one process.

Note that, in FIG. 10A and FIG. 10B, widths or quantities per unit area of the covering portions 63 are varied in the X axis direction such that the doping concentrations of the second conductivity type region formed in the respective regions are varied. In the present example, widths or quantities per unit area of the covering portions 63 are varied in the Y axis direction such that the doping concentrations of the anode region 84 of the extension region 81 may be varied.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: semiconductor substrate, 11: well region, 12: emitter region, 14: base region, 15: contact region, 16: accumulation region, 17: plug region, 18: drift region, 20: buffer region, 21: front surface, 22: collector region, 23: back surface, 24: collector electrode, 29: linear portion, 30: dummy trench portion, 31: edge portion, 32: dummy dielectric film, 34: dummy conductive portion, 38: interlayer dielectric film, 39: linear portion, 40: gate trench portion, 41: edge portion, 42: gate dielectric film, 44: gate conductive portion, 48: gate runner, 49: contact hole, 52: emitter electrode, 54: contact hole, 56: contact hole, 60: mesa portion, 61: mesa portion, 62: mask, 63: covering portion, 64: uncovering portion, 65: implanted region, 66: non-implanted region, 70: transistor portion, 71: main region, 72: end region, 80: diode portion, 81: extension region, 82: cathode region, 84: anode region, 90: boundary region, 100: semiconductor device, 102: end side, 120: edge termination structure portion, 160: active region, 200: semiconductor device, 300: semiconductor device

What is claimed is:

1. A fabrication method of a semiconductor device comprising a semiconductor substrate of a first conductivity type including a transistor portion and a diode portion and provided with a plurality of trench portions, comprising:
forming a mask above the semiconductor substrate such that a covering density for a predetermined first region of the semiconductor substrate by the mask is higher than a covering density for a predetermined second region of the semiconductor substrate by the mask;
performing ion implantation of a dopant in each of the first region and the second region for forming a second conductivity type region on a front surface of the semiconductor substrate; and
diffusing the implanted dopant into the semiconductor substrate,
wherein the mask includes a covering portion and an uncovering portion, a width of the covering portion is equal to or greater than 0.25 times and equal to or smaller than 0.8 times a diffusion depth of the dopant, a width of the uncovering portion is equal to or greater than one-third and equal to or smaller than once the width of the covering portion.

2. The fabrication method of a semiconductor device according to claim 1, wherein
the mask does not include the covering portion above the first region and at least includes the covering portion above the second region.

3. The fabrication method of a semiconductor device according to claim 1, wherein
the first region corresponds to a main region of the transistor portion and the second region corresponds to the diode portion.

4. The fabrication method of a semiconductor device according to claim 3, wherein
the second region includes a region corresponding to a boundary region on the diode portion side with respect to the main region.

5. The fabrication method of a semiconductor device according to claim 1, wherein
the covering portion is in a striped pattern extending in a trench array direction.

6. The fabrication method of a semiconductor device according to claim 1, wherein
a width of the covering portion is equal to or greater than 0.5 μm and equal to or smaller than 1.6 μm.

7. The fabrication method of a semiconductor device according to claim 1, wherein
performing ion implantation of a dopant includes performing ion implantation in each of the first region, the second region, and a predetermined third region of the semiconductor substrate, and
in a top view, an area ratio of the covering portion in the first region is lower than an area ratio of the covering portion in the second region, and an area ratio of the covering portion in the second region is lower than an area ratio of the covering portion in the third region.

8. The fabrication method of a semiconductor device according to claim 2, wherein
performing ion implantation of a dopant includes performing ion implantation in each of the first region, the second region, and a predetermined third region of the semiconductor substrate, and
in a top view, an area ratio of the covering portion in the first region is lower than an area ratio of the covering portion in the second region, and an area ratio of the covering portion in the second region is lower than an area ratio of the covering portion in the third region.

9. The fabrication method of a semiconductor device according to claim 3, wherein
performing ion implantation of a dopant includes performing ion implantation in each of the first region, the second region, and a predetermined third region of the semiconductor substrate, and
in a top view, an area ratio of the covering portion in the first region is lower than an area ratio of the covering portion in the second region, and an area ratio of the covering portion in the second region is lower than an area ratio of the covering portion in the third region.

10. The fabrication method of a semiconductor device according to claim 7, wherein
the first region corresponds to an end region on the diode portion side with respect to a main region of the transistor portion, the second region corresponds to the main region, and the third region corresponds to the diode portion.

11. The fabrication method of a semiconductor device according to claim 10, wherein
a doping concentration of the second conductivity type region formed in the end region is equal to or greater than 1.5 times and equal to or smaller than twice a doping concentration of the second conductivity type region formed in the main region.

12. The fabrication method of a semiconductor device according to claim 7, wherein
the mask does not include the covering portion above the first region and at least includes the covering portion above the second region and the third region.

13. The fabrication method of a semiconductor device according to claim 7, wherein
the first region corresponds to an end region on the diode portion side with respect to a main region of the transistor portion, the second region and the third region correspond to a region included in the main region, and a region corresponding to the third region is more spaced apart from the end region than a region corresponding to the second region.

14. The fabrication method of a semiconductor device according to claim 13, wherein
performing ion implantation of a dopant includes performing ion implantation in a predetermined fourth region of the semiconductor substrate,
in a top view, an area ratio of the covering portion in the third region is lower than an area ratio of the covering portion in the fourth region, and
the fourth region is the diode portion.

15. The fabrication method of a semiconductor device according to claim 13, wherein
a width of the end region in a trench array direction is equal to or greater than 20 μm and equal to or smaller than 100 μm.

16. The fabrication method of a semiconductor device according to claim 13, wherein
the covering portion is in a striped pattern extending in a trench array direction, and
a width of the covering portion is smaller than that of the second region in the first region and smaller than that of the third region in the second region.

17. The fabrication method of a semiconductor device according to claim 1, wherein
the first region includes a region corresponding to an extension region outer than an end of the diode portion in a trench extending direction.

18. The fabrication method of a semiconductor device according to claim 17, wherein
the plurality of trench portions extend to the extension region.

19. The fabrication method of a semiconductor device according to claim 1, wherein
the mask is a resist.

20. The fabrication method of a semiconductor device according to claim 1, wherein
a thickness of the covering portion is equal to or greater than 0.3 μm and equal to or smaller than 3 μm.
